(19) United States
(12) Patent Application Publication
(10) Pub. No.: US 2020/0128680 A1
(43) Pub. Date: Apr. 23, 2020

(54) CIRCUIT BOARD AND PLATING METHOD THEREOF

(71) Applicant: BOARDTEK ELECTRONICS CORPORATION, TAOYUAN CITY (TW)

(72) Inventor: CHIEN-CHENG LEE, TAOYUAN CITY (TW)

(21) Appl. No.: 16/237,001

(22) Filed: Dec. 31, 2018

(30) Foreign Application Priority Data
Oct. 19, 2018 (TW) 107136981

(51) Int. Cl. H05K 3/42; H05K 3/00; H05K 3/18; H05K 3/46; C23C 18/16

(52) U.S. Cl. CPC H05K 3/426; H05K 3/0094; C23C 18/1651; H05K 3/465; H05K 3/181

(57) ABSTRACT

A plating method of a circuit board includes first to fifth steps. The first step is implemented by providing a substrate, and the substrate has a first board surface and a second board surface opposite to the first board surface. The second step is implemented by forming a thru-hole in the substrate, and the thru-hole penetrates from the first board surface to the second board surface. The third step is implemented by detachably bonding a carrier onto the second board surface of the substrate to cover the thru-hole, and a portion of the carrier covering the thru-hole is defined as a plated region. The fourth step is implemented by plating the plated region of the carrier to form a metal post that is filled fully within the thru-hole. The fifth step is implemented by tearing off the carrier from the substrate and the metal post.

### CROSS-REFERENCE TO RELATED PATENT APPLICATION

This application claims the benefit of priority to Taiwan Patent Application No. 107136981, filed on Oct. 19, 2018. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a manufacturing method of a circuit board, and more particularly to a circuit board and a plating method thereof that uses a detachable carrier.

### BACKGROUND OF THE DISCLOSURE

Referring to FIG. 1, a conventional circuit board 100a includes a board portion 1a and a plated portion 2a. The board portion 1a has a thru-hole 11a, and the plated portion 2a is formed in the thru-hole 11a so as to provide a heat-dissipating effect. However, when the board portion 1a is plated to form the plated portion 2a in the thru-hole 11a, the plated portion 2a is often formed with a gap 200a therein, and the highly corrosive plating solution 300a remains in the gap 200a. At this time, after the circuit board 100a is used for a long time or repeatedly subjected to thermal expansion and contraction the plated portion 2a cannot entirely cover the plating solution 300a in the gap 200a, thereby causing the plating solution 300a to flow out and damaging the circuits or electronic components disposed on the circuit board 100a.

### SUMMARY OF THE DISCLOSURE

In response to the above-referenced technical inadequacies, the present disclosure provides a circuit board and a plating method thereof which improve the conventional circuit boards.

In one aspect, the present disclosure provides a plating method of a circuit board, which includes a first step to a fifth step. The first step is implemented by providing a substrate that has a first board surface and a second board surface opposite to the first board surface. The second step is implemented by forming a thru-hole in the substrate, and the thru-hole penetrates from the first board surface to the second board surface. The third step is implemented by detachably bonding a carrier onto the second board surface of the substrate so as to cover the thru-hole, and a portion of the carrier covering the thru-hole is defined as a plated region. The fourth step is implemented by plating the plated region of the carrier so as to form a metal post that is filled fully within the thru-hole. The fifth step is implemented by tearing off the carrier from the substrate and the metal post.

In certain embodiments, in the third step, the carrier is detachably bonded on the second board surface of the substrate through an adhesive layer, and wherein in the fifth step, the carrier and the adhesive layer are torn off from the substrate and the metal post at the same time, and a portion of the metal post protrudes from the second board surface of the substrate.

In certain embodiments, in the first step, the substrate includes an insulating board and a top conductive layer disposed on a top surface of the insulating board, and a surface of the top conductive layer away from the insulating board is defined as the first board surface, wherein in the second step, the insulating board has an inner surface defining the thru-hole, and the top surface of the insulating board has a reserved region that is exposed from the top conductive layer and is connected to the inner surface, and wherein in the fourth step, before the metal post is formed, a protecting layer is formed on the substrate to cover the first board surface and the reserved region.

In one aspect, the present disclosure provides a circuit board prepared by the plating method.

Therefore, in the circuit board and the plating method of the present disclosure, the metal post is formed in the thru-hole by plating the detachable carrier, thereby effectively preventing any bubbles from generating in the thru-hole of the substrate, increasing the manufacturing yield of the circuit board.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a schematic view of a conventional circuit board.

FIG. 2 is a perspective view showing a first step of a plating method of a circuit board according to a first embodiment of the present disclosure.

FIG. 3 is a cross-sectional view taken along line of FIG. 2.

FIG. 4 is a perspective view showing a second step of the plating method according to the first embodiment of the present disclosure.

FIG. 5 is a cross-sectional view taken along line V-V of FIG. 4.

FIG. 6 is a perspective view showing a third step of the plating method according to the first embodiment of the present disclosure.

FIG. 7 is a perspective view showing a fourth step of the plating method according to the first embodiment of the present disclosure.

FIG. 8 is a perspective view showing a fifth step of the plating method according to the first embodiment of the present disclosure.

FIG. 9 is a perspective view showing a third step of a plating method of a circuit board according to a second embodiment of the present disclosure.

FIG. 10 is a perspective view showing a fourth step of the plating method according to the second embodiment of the present disclosure.

FIG. 11 is a perspective view showing a fifth step of the plating method according to the second embodiment of the present disclosure.

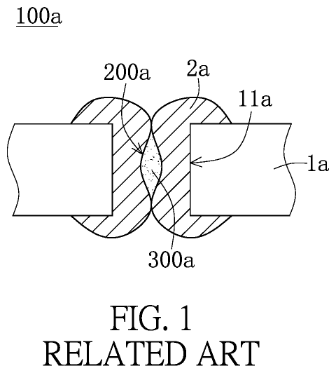

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

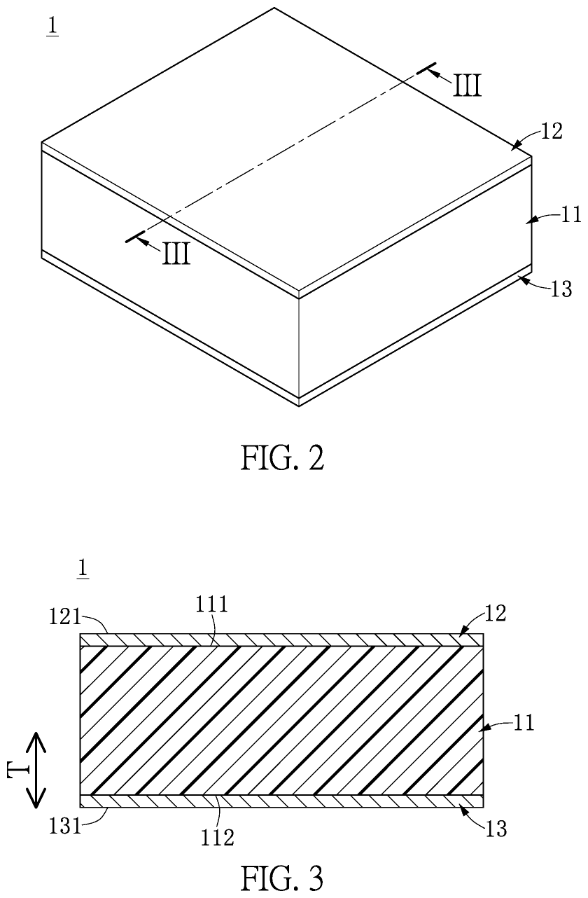

Referring to FIG. 2 to FIG. 8, a first embodiment of the present disclosure provides a circuit board and a plating method thereof, and the circuit board of the present embodiment is limited to being formed by implementing the plating method. Accordingly, the following description discloses the plating method of the present embodiment.

The plating method includes a first step to a fifth step, and the following description discloses each of the five steps, but the five steps of the present disclosure can be adjusted or changed according to design requirements.

As shown in FIG. 2 and FIG. 3, the first step is implemented by providing a substrate 1. The substrate 1 has a first board surface 121 and a second board surface 131 opposite to the first board surface 121.

The substrate 1 in the present embodiment includes an insulating board 11, a top conductive layer 12 disposed on a top surface 111 of the insulating board 11, and a bottom conductive layer 13 disposed on a bottom surface 112 of the insulating board 11. Moreover, a surface of the top conductive layer 12 away from the insulating board 11 is defined as the first board surface 121, and a surface of the bottom conductive layer 13 away from the insulating board 11 is defined as the second board surface 131.

It should be noted that, in other embodiments of the present disclosure, the substrate 1 can be provided with the insulating board 11, the insulating board and the top conductive layer 12, or the insulating board 11 and the bottom conductive layer 13.

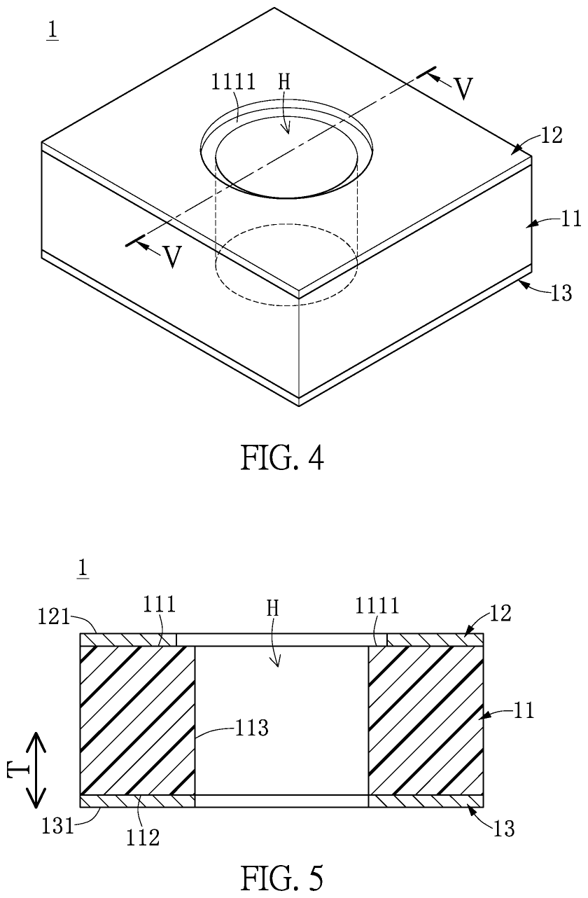

As shown in FIG. 4 and FIG. 5, the second step is implemented by forming a thru-hole H in the substrate 1, and the thru-hole H penetrates from the first board surface 121 to the second board surface 131. In the present embodiment, the thru-hole H is formed along a thickness direction T of the substrate 1, and a cross-section of the thru-hole H perpendicular to the thickness direction T is a circular shape, a square shape, a rectangular shape, or other shapes.

Moreover, the thru-hole H in the present embodiment is formed by mechanically drilling the substrate 1, so that the forming efficiency of the thru-hole H of the substrate 1 can be effectively increased. In other words, the thru-hole formed by a laser (and mechanically) drilling the substrate 1 has a forming efficiency lower than the forming efficiency of the thru-hole H disclosed in the second step of the present embodiment, and does not disclose the second step of the present embodiment.

Specifically, the insulating board 11 has an inner surface 113 defining the thru-hole H, and two opposite edges of the inner surface 113 are respectively connected to the top surface 111 and the bottom surface 112 of the insulating board 11. The top surface 111 of the insulating board 11 in the present embodiment preferably includes an annular reserved region 1111 that is exposed from the top conductive layer 12 and is connected to the inner surface 113. In other words, before the thru-hole H is formed in the substrate 1, the top conductive layer 12 can be processed (e.g., a part of the conductive layer 12 corresponding in position to the thru-hole H and the reserved region 1111 is removed), so that the substrate 1 can have the reserved region 1111 after the thru-hole H is formed in the substrate 1.

It should be noted that, the insulating board 11 is provided without any conductive material on the inner surface 113 thereof. In other words, if the insulating board is provided with a conductive material on the inner surface thereof, the thru-hole is different from the thru-hole H formed by implementing the second step of the present embodiment.

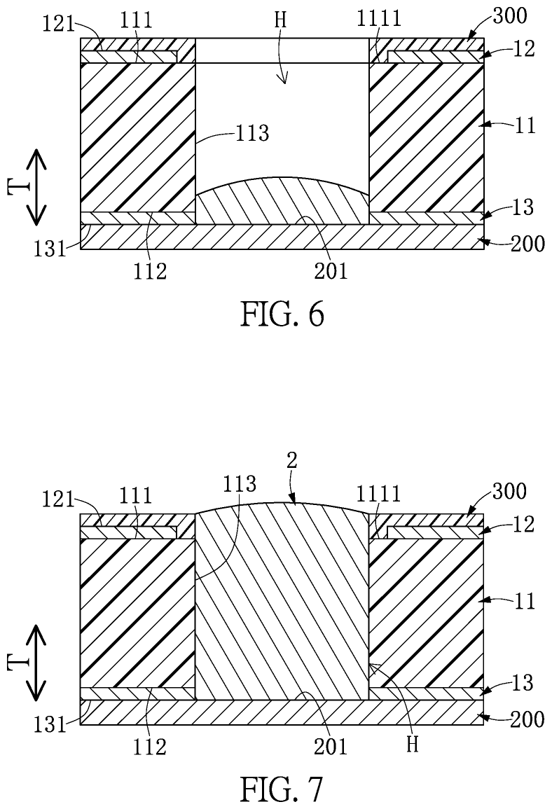

As shown in FIG. 6, the third step is implemented by detachably bonding a carrier 200 onto the second board surface 131 of the substrate 1 so as to cover the thru-hole H of the insulating board 11. The carrier 200 in the present embodiment is a conductive tape, but the present disclosure is not limited thereto. Moreover, a portion of the carrier 200 covering the thru-hole H is defined as a plated region 201. In other words, a conductive portion of the carrier 200 can be arranged on the plated region 201 only, and a portion of the carrier 200 other than the plated region 201 can be formed of an insulating material.

As shown in FIG. 7, the fourth step is implemented by plating the plated region 201 of the carrier 200 so as to form a metal post 2 that is filled fully within the thru-hole H. Since the insulating board 11 is provided without any conductive material on the inner surface 113 thereof, the metal post 2 filled fully within the thru-hole H is gradually formed just along a single direction (e.g., an upward direction shown in FIG. 7) by plating the plated region 201 of the carrier 200. Accordingly, the forming of the metal post 2 is not affected by the shape of the thru-hole H, so that the cross-section of the thru-hole H of the substrate 1 is not limited to a circular shape.

Specifically, before the metal post 2 is formed (or before the carrier 200 is plated to form the metal post 2) in the fourth step, a protecting layer 300 is formed on the substrate 1 to cover the first board surface 121 and the reserved region 1111. Moreover, a portion of the protecting layer 300 covering the reserved region 1111 has an inner side flush with the inner surface 113 of the insulating board 11. Accordingly, since the reserved region 1111 is covered by the protecting layer 300, a metal nodule (e.g., a copper nodule) can be effectively avoided to form on the top edge of the inner surface 113 of the substrate 1.

It should be noted that, the metal post 2 is gaplessly connected to the entire inner surface 113 of the insulating board 11, and the metal post 2 in the present embodiment is provided to dissipate heat, but the present disclosure is not limited thereto.

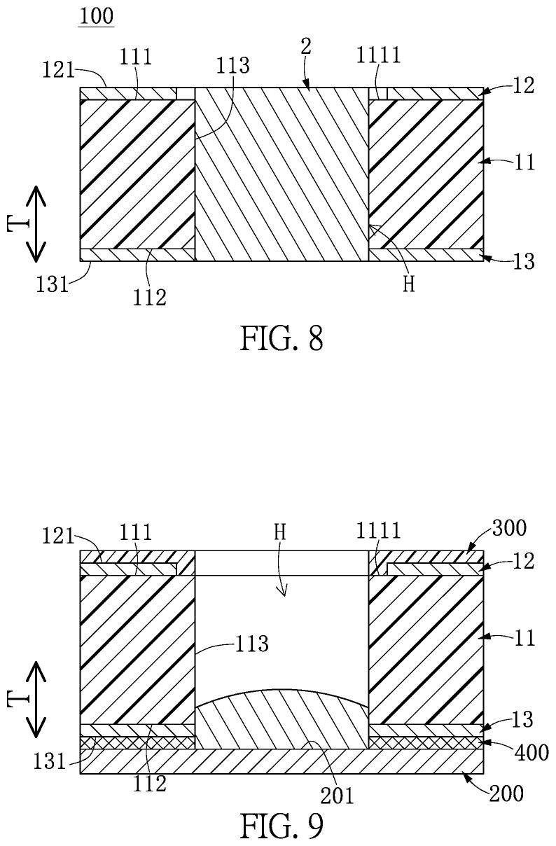

As shown in FIG. 8, the fifth step is implemented by tearing off the carrier 200 from the substrate 1 and the metal post 2 so as to obtain a circuit board 100. In addition, the circuit board 100 of the present disclosure can be manufactured by implementing steps (e.g., the protecting layer 300 is removed, or a portion of the metal post 2 protruding from the first board surface 121 can be removed so as to allow the metal post 2 to be coplanar with the first board surface 121) other than the first to fifth steps of the present embodiment.

### Second Embodiment

Referring to FIG. 9 to FIG. 11, a second embodiment of the present disclosure provides a plating method of a circuit board that includes a first step to a fifth step. Some steps (e.g., the first step and the second step) of the plating method in the present embodiment are similar to the corresponding steps of the plating method disclosed in the first embodiment, so that the following description discloses only the different features of the present embodiment for the sake of brevity.

As shown in FIG. 9, the third step is implemented by using an adhesive layer 400 to detachably bond the carrier 200 onto the second board surface 131 of the substrate 1 so as to cover the thru-hole H of the insulating board 11. In the present embodiment, the carrier 200 can be a metal plate (e.g., a stainless steel plate) or a carrying plate that is coated with a conductive film having the plated region 201, but the present disclosure is not limited thereto. In other words, a conductive portion of the carrier 200 can be only arranged on the plated region 201, and a portion of the carrier 200 other than the plated region 201 can be formed of an insulating material.

Moreover, the adhesive layer 400 in the present embodiment has a thickness that is within a range of 5-50 μm, but the thickness of the adhesive layer 400 in other embodiments of the present disclosure can be adjusted or changed according to design requirements. For example, the thickness of the adhesive layer 400 can be within a range of 20-30 μm.

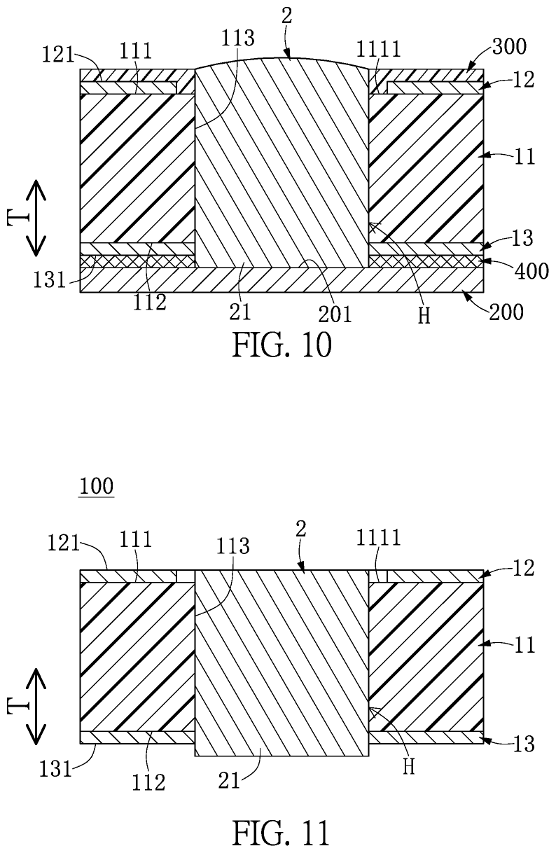

As shown in FIG. 10, the fourth step is implemented by plating the plated region 201 of the carrier 200 so as to form a metal post 2 that is filled fully within the thru-hole H. The fourth step of the present embodiment is similar to that of the first embodiment, and the different features of the fourth step of the present embodiment are disclosed as follows. A portion of the metal post 2 protrudes from the second board surface 131 of the substrate 1, and is defined as a protrusion 21 that has a thickness less than or equal to the thickness of the adhesive layer 400.

As shown in FIG. 11, the fifth step is implemented by tearing off the carrier 200 along with the adhesive layer 400 from the substrate 1 and the metal post 2 at the same time, so as to obtain a circuit board 100. The protrusion 21 of the metal post 2 of the circuit board 100 protrudes from the second board surface 131 of the substrate 1.

It should be noted that, since the metal post 2 of the circuit board 100 is used to abut against a component (not shown) that needs to dissipate heat, the metal post 2 needs to be partially protruded from the substrate 1 so as to ensure that the metal post 2 can be effectively abutted against the component. However, in a conventional plating method, a plated portion formed in a thru-hole of a board portion, and then a part of the plated portion protruding from the board portion is grinded to have a predetermined thickness. In the present embodiment, the protrusion 21 of the metal post 2 can be preciously formed with a predetermined thickness by implementing the plating method, so that the metal post 2 in the present embodiment doesn't need to be grinded, thereby reducing the manufacturing cost.

In addition, a bonding force of the adhesive layer 400 relative to the second board surface 131 of the substrate 1 can be reduced, and then the carrier 200 and the adhesive layer 400 are torn off from the substrate 1 and the metal post 2 at the same time. For example, the adhesive layer 400 can be at least one of a pyrolytic tape, a heat-resistance tape, and a UV tape. Accordingly, the adhesive layer 400 can be heated, irradiated with UV light, or contact with an organic solution (e.g., acetone, ethyl ketone, or isopropanol) according to the type of the adhesive layer 400, so that the bonding force of the adhesive layer 400 relative to the second board surface 131 of the substrate 1 can be reduced.

In conclusion, in the circuit board and the plating method of the present disclosure, the metal post is formed in the thru-hole by plating the detachable carrier, thereby effectively preventing any bubbles from generating in the thru-hole of the substrate, increasing the manufacturing yield of the circuit board.

Moreover, in the circuit board and the plating method of the present disclosure, since the reserved region is covered by the protecting layer, a metal nodule (e.g., a copper nodule) can be effectively avoided to form on the top edge of the inner surface of the substrate.

In addition, the protrusion of the metal post of the circuit board can be preciously formed with a predetermined thickness by implementing the plating method of the present disclosure, so that the metal post doesn't need to be grinded, thereby reducing the manufacturing cost.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A plating method of a circuit board, comprising:
a first step implemented by providing a substrate, wherein the substrate has a first board surface and a second board surface opposite to the first board surface;
a second step implemented by forming a thru-hole in the substrate, wherein the thru-hole penetrates from the first board surface to the second board surface;
a third step implemented by detachably bonding a carrier onto the second board surface of the substrate so as to cover the thru-hole, wherein a portion of the carrier covering the thru-hole is defined as a plated region;
a fourth step implemented by plating the plated region of the carrier so as to form a metal post that is filled fully within the thru-hole; and
a fifth step implemented by tearing the carrier off from the substrate and the metal post.

2. The plating method according to claim 1, wherein in the first step, the substrate includes an insulating board and a bottom conductive layer disposed on a bottom surface of the insulating board, and a surface of the bottom conductive layer away from the insulating board is defined as the second board surface.

3. The plating method according to claim 2, wherein in the second step, the thru-hole is formed by mechanically drilling the substrate, the insulating board has an inner surface defining the thru-hole, and the insulating board is provided without any conductive material on the inner surface thereof, and wherein in the fourth step, the metal post filled fully within the thru-hole is formed along a single direction by plating the plated region of the carrier.

4. The plating method according to claim 1, wherein in the third step, the carrier is detachably bonded on the second board surface of the substrate through an adhesive layer, and wherein in the fifth step, the carrier and the adhesive layer are torn off from the substrate and the metal post at the same time, and a portion of the metal post protrudes from the second board surface of the substrate.

5. The plating method according to claim 4, wherein the adhesive layer has a thickness that is within a range of 5-50 μm, and the portion of the metal post protruding from the second board surface has a thickness that is less than or equal to the thickness of the adhesive layer.

6. The plating method according to claim 4, wherein in the fifth step, a bonding force of the adhesive layer relative to the second board surface of the substrate is reduced, and then the carrier and the adhesive layer are torn off from the substrate and the metal post at the same time.

7. The plating method according to claim 1, wherein in the first step, the substrate includes an insulating board and a top conductive layer disposed on a top surface of the insulating board, and a surface of the top conductive layer away from the insulating board is defined as the first board surface, wherein in the second step, the insulating board has an inner surface defining the thru-hole, and the top surface of the insulating board has a reserved region that is exposed from the top conductive layer and is connected to the inner surface, and wherein in the fourth step, before the metal post is formed, a protecting layer is formed on the substrate to cover the first board surface and the reserved region.

8. The plating method according to claim 7, wherein a portion of the protecting layer covering the reserved region has an inner side flush with the inner surface of the insulating board.

9. The plating method according to claim 1, wherein the carrier includes a conductive tape, a metal plate, or a carrying plate that is coated with a conductive film having the plated region.

10. A circuit board prepared by the plating method according to claim 1.
